(19) United States
(12) Patent Application Publication
(10) Pub. No.: US 2025/0230548 A1
(43) Pub. Date: Jul. 17, 2025

(54) METHOD OF CONTROLLING ATMOSPHERE, METHOD OF PROCESSING SUBSTRATE, METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: KOKUSAI ELECTRIC CORPORATION, Tokyo (JP)

(72) Inventors: Kaoru YAMAMOTO, Toyama-shi (JP); Naofumi OHASHI, Toyama-shi (JP)

(73) Assignee: KOKUSAI ELECTRIC CORPORATION, Tokyo (JP)

(21) Appl. No.: 19/022,254

(22) Filed: Jan. 15, 2025

(30) Foreign Application Priority Data
Jan. 16, 2024 (JP) 2024-004746

(51) Int. Cl. C23C 16/52; C23C 16/40; H01L 21/02

(52) U.S. Cl. CPC C23C 16/52; C23C 16/401; H01L 21/02271

(57) ABSTRACT

It is possible to reduce a consumption amount of an inert gas. There is provided a technique that includes: (a) moving a substrate between a first vessel and a second vessel wherein a substrate is processed in the second vessel and the first vessel is capable of communicating with the second vessel; (b) processing the substrate in the second vessel; and (c) waiting without processing the substrate in the second vessel, wherein an amount of an inert gas supplied into the first vessel in a state where an inner pressure of the first vessel is higher than that of the second vessel is adjusted such that the amount in (a) is greater than one or both of the amount in (b) and the amount in (c).

### CROSS-REFERENCE TO RELATED PATENT APPLICATION

This non-provisional U.S. patent application is based on and claims priority under 35 U.S.C. § 119 of Japanese Patent Application No. 2024-004746 filed on Jan. 16, 2024, in the Japanese Patent Office, the entire contents of which are hereby incorporated by reference.

### BACKGROUND

### 1. Field

The present disclosure relates to a method of controlling an atmosphere, a method of processing a substrate, a method of manufacturing a semiconductor device, a substrate processing apparatus and a non-transitory computer-readable recording medium.

### 2. Related Art

A substrate processing apparatus is used in a part of a manufacturing process of a semiconductor device. According to some related arts, for example, the substrate processing apparatus may include: a process chamber in which a substrate is processed; and a transfer chamber capable of communicating with the process chamber. For example, the substrate processing apparatus may be configured such that an inert gas can be supplied into each of the process chamber and the transfer chamber.

### SUMMARY

According to the present disclosure, there is provided a technique capable of reducing a consumption amount of an inert gas.

According to an embodiment of the present disclosure, there is provided a technique that includes: (a) moving a substrate between a first vessel and a second vessel wherein a substrate is processed in the second vessel and the first vessel is capable of communicating with the second vessel; (b) processing the substrate in the second vessel; and (c) waiting without processing the substrate in the second vessel, wherein an amount of an inert gas supplied into the first vessel in a state where an inner pressure of the first vessel is higher than that of the second vessel is adjusted such that the amount in (a) is greater than one or both of the amount in (b) and the amount in (c).

### BRIEF DESCRIPTION OF THE DRAWINGS

FIG. 1 is a diagram schematically illustrating a horizontal cross-section of an example of an overall configuration of a substrate processing apparatus according to one or more embodiments of the present disclosure.

FIG. 2 is a diagram schematically illustrating a vertical cross-section of the example of the overall configuration of the substrate processing apparatus according to the embodiments of the present disclosure.

FIG. 3 is a diagram schematically illustrating an example of a configuration of a process chamber of the substrate processing apparatus according to the embodiments of the present disclosure.

FIG. 4 is a diagram schematically illustrating an example of a configuration of a fourth gas supplier of the substrate processing apparatus according to the embodiments of the present disclosure.

FIG. 5 is a diagram schematically illustrating an example of a configuration of a fifth gas supplier of the substrate processing apparatus according to the embodiments of the present disclosure.

FIG. 6 is a diagram schematically illustrating an example of a configuration of a sixth gas supplier of the substrate processing apparatus according to the embodiments of the present disclosure.

FIG. 7 is a block diagram schematically illustrating an example of a configuration of a controller of the substrate processing apparatus according to the embodiments of the present disclosure.

FIG. 8 is a flow chart schematically illustrating an overview of a substrate processing according to the embodiments of the present disclosure.

FIG. 9 is a diagram schematically illustrating a vertical cross-section of an example of an overall configuration of a substrate processing apparatus according to another embodiment of the present disclosure.

### DETAILED DESCRIPTION

Hereinafter, one or more embodiments (also simply referred to as “embodiments”) according to the technique of the present disclosure will be described with reference to the drawings.

A substrate processing apparatus exemplified in the following description can be used in a manufacturing process of a semiconductor device, and is configured to perform a predetermined treatment process on a substrate to be processed. For example, a silicon wafer (hereinafter, also simply referred to as a “wafer”) may be used as the substrate to be processed. The silicon wafer may serve as a semiconductor substrate on which the semiconductor device is manufactured. Further, in the present specification, the term “substrate” may refer to “a substrate itself”, or may refer to “a substrate and a stacked structure (aggregated structure) of a predetermined layer (or layers) or a film (or films) formed on a surface of the substrate”. That is, the term “substrate” may collectively refer to “a substrate and layers or films formed on a surface of the substrate”. Further, in the present specification, the term “a surface of a substrate” may refer to “a surface (exposed surface) of a substrate itself”, or may refer to “a surface of a predetermined layer or a film formed on a substrate, i.e. a top surface (uppermost surface) of the substrate as a stacked structure”. In the present specification, the terms “substrate” and “wafer” may be used as substantially the same meaning. That is, the term “substrate” may be substituted by “wafer” and vice versa. For example, the predetermined treatment process (hereinafter, may also be simply referred to as “process”) performed on the substrate may include a process such as an oxidation process, a diffusion process, an annealing process, an etching process, a pre-cleaning process, a chamber cleaning process and a film forming process. The present embodiments will be described by way of an example in which the film forming process is performed.

The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Overall Configuration of Substrate Processing Apparatus

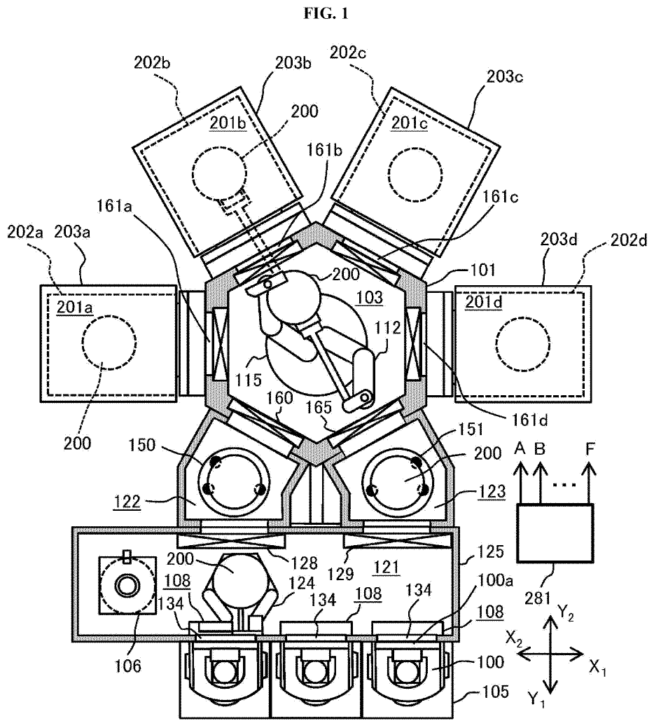

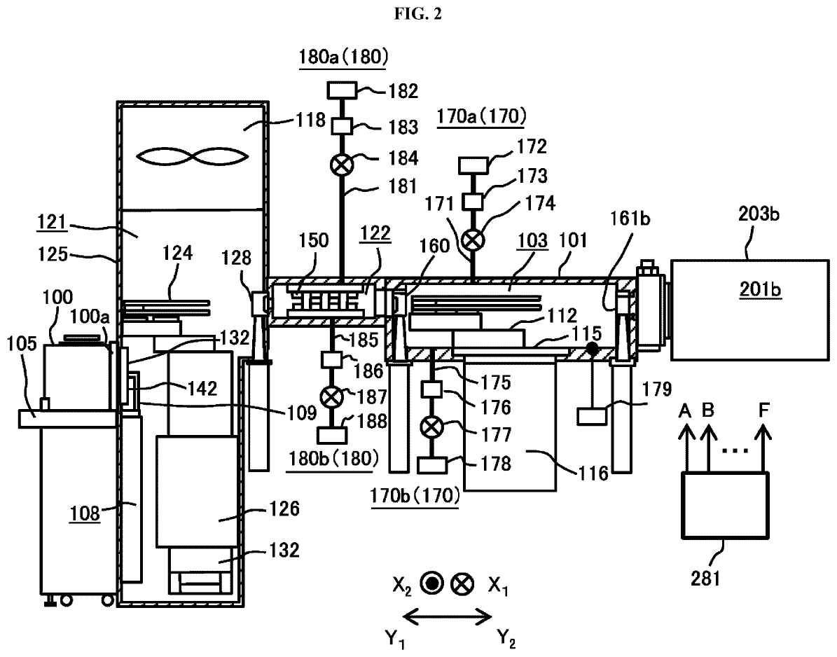

An overall configuration of the substrate processing apparatus according to the present embodiments will be described with reference to FIGS. 1 and 2. FIG. 1 is a diagram schematically illustrating a horizontal cross-section of an example of the overall configuration of the substrate processing apparatus according to the present embodiments. FIG. 2 is a diagram schematically illustrating a vertical cross-section of the example of the overall configuration of the substrate processing apparatus according to the present embodiments.

As shown in FIGS. 1 and 2, the substrate processing apparatus described as an example in the present embodiments is a so-called cluster type apparatus which includes a plurality of process modules 201a to 201d around a vacuum transfer chamber 103. More specifically, the substrate processing apparatus described as the example in the present embodiments is configured to process a substrate 200. For example, the substrate processing apparatus is constituted mainly by: the vacuum transfer chamber (transfer module) 103; two load lock chambers (load lock modules) 122 and 123; an atmospheric transfer chamber (front end module) 121; an I/O (input/output) stage (loading port structure) 105; the plurality of process modules (processing structures) 201a to 201d; and a controller 281 as a control structure. Hereinafter, each of the components mentioned above will be described in detail. In the following description, front, rear, left and right directions are indicated by an arrow Y₁, an arrow Y₂, an arrow X₂ and an arrow X₁ shown in FIG. 1, respectively.

### <Vacuum Transfer Chamber>

The vacuum transfer chamber 103 serves as a transfer chamber, that is, a transfer space into which the substrate 200 is transferred under a negative pressure. A housing 101 (which constitutes the vacuum transfer chamber 103) is provided in a hexagonal shape when viewed from above. The housing 101 may also be referred to as a “first vessel”. The load lock chambers 122 and 123 and the process modules 201a to 201d are connected to respective sides of the housing 101 of the hexagonal shape via gate valves 160, 165 and 161a to 161d.

A vacuum transfer robot 112 capable of transferring (or transporting) the substrate 200 under the negative pressure is provided at approximately a center of the vacuum transfer chamber 103 with a flange 115 as a base. The vacuum transfer robot 112 is configured to be capable of being elevated or lowered while maintaining an airtightness of the vacuum transfer chamber 103 by an elevator 116 and the flange 115 (see FIG. 2).

The vacuum transfer chamber 103 is provided with a first atmosphere regulator (which is a first atmosphere adjusting structure) 170 capable of adjusting (regulating) an atmosphere (inner atmosphere) of the vacuum transfer chamber 103. For example, the first atmosphere regulator 170 includes a first gas supplier (which is a first gas supply structure) 170a capable of supplying an inert gas to the vacuum transfer chamber 103, and a first exhauster (which is a first exhaust structure) 170b capable of exhausting the inner atmosphere of the vacuum transfer chamber 103 (see FIG. 2).

The first gas supplier 170a includes a first gas supply pipe 171 communicating with an inside of the vacuum transfer chamber 103. For example, a first gas source 172, a mass flow controller (MFC) 173 serving as a flow rate controller (flow rate control structure) and a valve 174 serving as an opening/closing valve are sequentially installed at the first gas supply pipe 171 in this order from an upstream side to a downstream side of the first gas supply pipe 171 in a gas flow direction. The first gas source 172 is an inert gas source. For example, as the inert gas, nitrogen (N₂) gas is used. For example, the first gas supplier 170a is constituted mainly by the first gas supply pipe 171, the MFC 173 and the valve 174.

The first exhauster 170b includes an exhaust pipe 175 communicating with the inside of the vacuum transfer chamber 103. For example, an APC (Automatic Pressure Controller) 176 serving as a pressure controller capable of controlling a pressure (inner pressure) of the vacuum transfer chamber 103 to a predetermined pressure is provided at the exhaust pipe 175. The APC 176 includes a valve body (not shown) whose opening degree is capable of being adjusted, and is configured to adjust a conductance of the exhaust pipe 175 in response to an instruction from the controller 281. In addition, a valve 177 is provided at the exhaust pipe 175 at a downstream side of the APC 176. The exhaust pipe 175, the valve 177 and the APC 176 may also be collectively referred to as the “first exhauster 170b”. In addition, a DP (Dry Pump) 178 is provided at a downstream side of the exhaust pipe 175. The DP 178 is configured to exhaust the inner atmosphere of the vacuum transfer chamber 103 via the exhaust pipe 175.

The vacuum transfer chamber 103 is provided with a first pressure meter (which is a first pressure measuring structure) 179 capable of measuring the inner pressure of the vacuum transfer chamber 103. For example, the first pressure meter 179 may be configured using a pressure sensor. The first pressure meter 179 is configured such that a pressure measurement result measured by the first pressure meter 179 is output to the controller 281 described later.

### <Load Lock Chamber>

The load lock chamber 122 through which the substrate 200 is loaded and the load lock chamber 123 through which the substrate 200 is unloaded are connected to two side walls (among six side walls of the housing 101 constituting the vacuum transfer chamber 103) located at the front via the gate valves 160 and 165, respectively. A substrate placement table 150 where the substrate 200 is loaded is installed in the load lock chamber 122, and a substrate placement table 151 where the substrate 200 is unloaded is installed in the load lock chamber 123. Each of the load lock chambers 122 and 123 is constructed to be capable of withstanding the negative pressure.

Each of the load lock chambers 122 and 123 is provided with a third atmosphere regulator (which is a third atmosphere adjusting structure) 180 capable of adjusting an atmosphere (inner atmosphere) of each of the load lock chambers 122 and 123. For example, the third atmosphere regulator 180 includes a third gas supplier (which is a third gas supply structure) 180a capable of supplying the inert gas to each of the load lock chambers 122 and 123, and a third exhauster (which is a third exhaust structure) 180b capable of exhausting the inner atmosphere of each of the load lock chambers 122 and 123 (see FIG. 2).

The third gas supplier 180a includes a third gas supply pipe 181 communicating with an inside of each of the load lock chambers 122 and 123. For example, a third gas source 182, a mass flow controller (MFC) 183 serving as a flow rate controller (flow rate control structure) and a valve 184 serving as an opening/closing valve are sequentially installed at the third gas supply pipe 181 in this order from an upstream side to a downstream side of the third gas supply pipe 181 in the gas flow direction. The third gas source 182 is an inert gas source. For example, as the inert gas, the nitrogen (N₂) gas is used. The third gas source 182 may be shared with the first gas source 172 of the first gas supplier 170a. For example, the third gas supplier 180a is constituted mainly by the third gas supply pipe 181, the MFC 183 and the valve 184.

The third exhauster 180b includes an exhaust pipe 185 communicating with the inside of each of the load lock chambers 122 and 123. For example, an APC 186 serving as a pressure controller capable of controlling a pressure (inner pressure) of each of the load lock chambers 122 and 123 to a predetermined pressure is provided at the exhaust pipe 185. The APC 186 includes a valve body (not shown) whose opening degree is capable of being adjusted, and is configured to adjust a conductance of the exhaust pipe 185 in response to an instruction from the controller 281. In addition, a valve 187 is provided at the exhaust pipe 185 at a downstream side of the APC 186. The exhaust pipe 185, the valve 187 and the APC 186 may also be collectively referred to as the “third exhauster 180b”. In addition, a DP (Dry Pump) 188 is provided at a downstream side of the exhaust pipe 185. The DP 188 is configured to exhaust the inner atmosphere of each of the load lock chambers 122 and 123 via the exhaust pipe 185. The DP 188 may be shared with the DP 178 of the first exhauster 170b.

### <Atmospheric Transfer Chamber>

The atmospheric transfer chamber 121 is connected to front sides of the load lock chambers 122 and 123 via gate valves 128 and 129. The atmospheric transfer chamber 121 is used under approximately atmospheric pressure.

An atmospheric transfer robot 124 capable of transferring the substrate 200 is provided in the atmospheric transfer chamber 121. The atmospheric transfer robot 124 is configured to be elevated or lowered by an elevator 126 installed in the atmospheric transfer chamber 121 and to be reciprocated laterally (that is, in a left-right direction) by a linear actuator 132 (see FIG. 2).

A clean air supplier (which is a clean air supply structure) 118 capable of supplying clean air is installed at an upper portion of the atmospheric transfer chamber 121 (see FIG. 2). In addition, on a left side of the atmospheric transfer chamber 121, a device (hereinafter, also referred to as a “pre-aligner”) 106 capable of aligning a notch or an orientation flat formed on the substrate 200 is installed (see FIG. 1).

### <I/O Stage>

A substrate loading/unloading port 134 through which the substrate 200 is loaded into or unloaded from the atmospheric transfer chamber 121 and a pod opener 108 are provided at a front side of a housing 125 of the atmospheric transfer chamber 121. The I/O stage 105 is provided opposite to the pod opener 108 with the substrate loading/unloading port 134 interposed therebetween. That is, the I/O stage 105 is provided outside the housing 125.

The I/O stage 105 is configured such that a plurality of FOUPs (Front Opening Unified Pods, hereinafter, also referred to as “pods”) 100 can be placed on the I/O stage 105. Hereinafter, each of the plurality of pods 100 may also be simply referred to as a “pod 100”. The pod 100 is configured such that a plurality of substrates including the substrate 200 can be accommodated therein. Hereinafter, the plurality of substrates including the substrate 200 may also be simply referred to as “substrates 200”. The pod 100 is used as a carrier for transferring the substrate 200 such as a silicon (Si) substrate. In addition, the pod 100 is configured such that the substrates 200 which are processed or the substrates 200 which are unprocessed can be accommodated in a multistage manner in a horizontal orientation in the pod 100.

The pod 100 on the I/O stage 105 can be opened or closed by the pod opener 108. The pod opener 108 is configured to open and close a cap 100a of the pod 100, and includes a closure 142 capable of closing the substrate loading/unloading port 134, and a driver (which is a driving structure) 109 capable of driving the closure 142.

### <Process Module>

The process modules 201a to 201d configured to perform a desired process (or desired processes) on the substrate 200 are connected to four side walls (among the six side walls of the housing 101 constituting the vacuum transfer chamber 103 other than the two side walls to which the load lock chambers 122 and 123 are connected) via the gate valves 161a to 161d, respectively. The process modules 201a to 201d are connected to the vacuum transfer chamber 103 so as to be located radially around the vacuum transfer chamber 103. The process modules 201a to 201d are configured as cold wall type process vessels 203a to 203d, respectively, and are provided with process chambers 202a to 202d, respectively. The process vessels 203a to 203d may also be collectively or individually referred to as a “second vessel”. In each of the process chambers 202a to 202d, the process (or the processes) can be performed on the substrate 200 as a part of the manufacturing process of the semiconductor device or a semiconductor. For example, the process performed in each of the process chambers 202a to 202d may include various substrate processing such as a process of forming a film on the substrate 200 (that is, the film forming process), a process of oxidizing, nitriding, carbonizing or modifying a surface of the substrate 200, a process of forming a film such as silicide and metal, a process of etching the surface of the substrate 200, and a reflow process.

A configuration of each of the process modules 201a to 201d will be described in detail later.

### <Controller>

The controller 281 functions as the control structure (control apparatus) capable of controlling operations of components constituting the substrate processing apparatus. Thus, the controller 281 serving as the control structure is configured by a computer (computing apparatus) including components such as a CPU (Central Processing Unit) 401 and a RAM (Random Access Memory) 402.

A configuration of the controller 281 will be described in detail later.

### (2) Configuration of Process Module

Hereinafter, the configuration of each of the process modules 201a to 201d will be described in detail.

Each of the process modules 201a to 201d functions as a single wafer type substrate processing apparatus. In addition, configurations of the process modules 201a to 201d are substantially the same. Thus, the configuration of each of the process modules 201a to 201d will be described in detail using one of the process modules 201a to 201d as an example. Because one of the process modules 201a to 201d is used as the example, in the following description, the process modules 201a to 201d may also be collectively or individually referred to as a “process module 201”, the cold wall type process vessels 203a to 203d constituting each of the process modules 201a to 201d may also be collectively or individually referred to as a “cold wall type process vessel 203” or a “process vessel 203”, the process chambers 202a to 202d provided in each of the process vessels 203a to 203d may also be collectively or individually referred to as a “process chamber 202”, and the gate valves 161a to 161d corresponding to each of the process modules 201a to 201d may also be collectively or individually referred to as a “gate valve 161”.

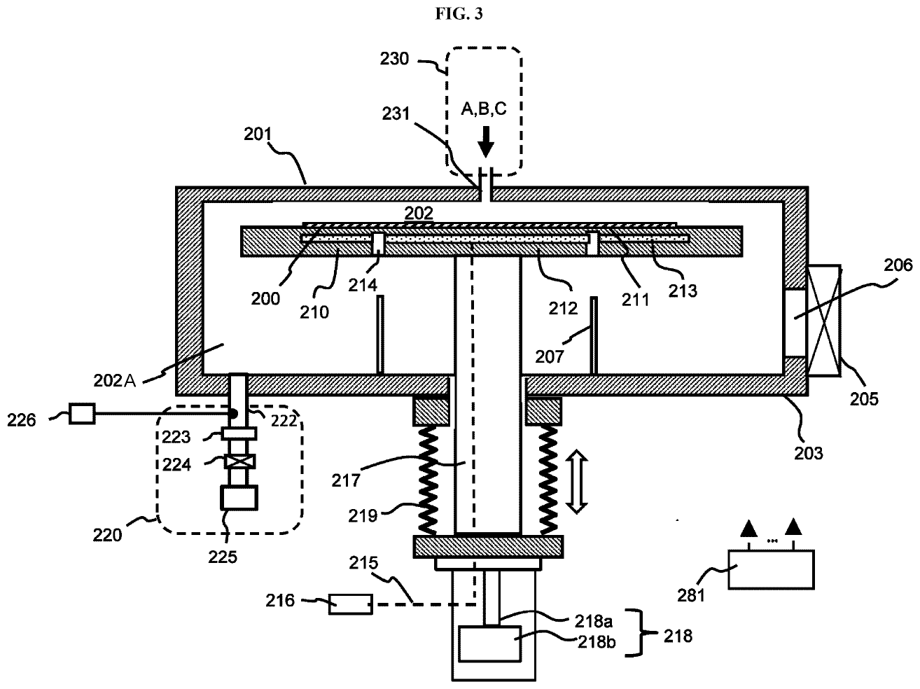

FIG. 3 is a diagram schematically illustrating an example of a configuration of the process chamber 202 of the substrate processing apparatus according to the present embodiments.

### <Process Vessel>

As described above, the process module 201 is constituted by the cold wall type process vessel 203. For example, the process vessel (hereinafter, also simply referred to as a “vessel”) 203 is configured as a flat sealed vessel whose horizontal cross-section is circular. For example, the vessel 203 is made of a metal material such as aluminum (Al) and stainless steel (SUS). The process chamber 202 constituting a process space in which the substrate 200 such as the silicon wafer is processed is provided in the vessel 203. In addition, a transfer space 202A through which the substrate 200 passes when being transferred to the process chamber 202 is provided below the process chamber 202.

A substrate loading/unloading port 206 adjacent to a gate valve 205 is provided on a side surface of the vessel 203, and the substrate 200 moves between the vessel 203 and the vacuum transfer chamber 103 via the substrate loading/unloading port 206. A plurality of lift pins 207 are provided at a lower portion of the vessel 203. In addition, an exhaust pipe 222 described later is provided.

A second pressure meter (which is a second pressure measuring structure) 226 capable of measuring a pressure (inner pressure) of the process chamber 202 is provided at the exhaust pipe 222. For example, the second pressure meter 226 may be configured using a pressure sensor. The second pressure meter 226 is configured such that a pressure measurement result measured by the second pressure meter 226 is output to the controller 281 described later. However, the second pressure meter 226 may be provided at a location other than that of the exhaust pipe 222 as long as the second pressure meter 226 is capable of measuring the inner pressure of the process chamber 202.

A substrate support 210 configured to support the substrate 200 is provided in the vessel 203. The substrate support 210 mainly includes: a substrate mounting table 212 provided with a substrate placing surface 211 on a surface thereof, where the substrate 200 is placed on the substrate placing surface 211; and a heater 213 serving as a heating structure provided in the substrate mounting table 212. A plurality of through-holes 214 through which the lift pins 207 penetrate are provided at positions of the substrate mounting table 212 corresponding to the lift pins 207.

A wiring 215 through which an electric power is supplied (applied) is connected to the heater 213. The wiring 215 is also connected to a heater controller 216.

The heater controller 216 is electrically connected to the controller 281 described later. The controller 281 is configured to transmit control information to the heater controller 216. The heater controller 216 is configured to control the heater 213 by referring to the control information when receiving the control information.

The substrate mounting table 212 is supported by a shaft 217. The shaft 217 penetrates the lower portion of the vessel 203, and is connected to an elevator (which is an elevating structure) 218 at an outside of the vessel 203.

The elevator 218 mainly includes: a support shaft 218a configured to support the shaft 217; and an operating structure 218b configured to elevate/lower or rotate the support shaft 218a. For example, the operating structure 218b may include: an elevator (not shown) such as a motor capable of elevating and lowering the support shaft 218a; and a rotator (which is a rotating structure) (not shown) such as a gear capable of rotating the support shaft 218a. The elevator 218 may further include an instruction controller (not shown) serving as a part of the elevator 218 and capable of controlling the operating structure 218b to move the support shaft 218a up and down or to rotate the support shaft 218a. The instruction controller is electrically connected to the controller 281. The instruction controller is configured to control the operating structure 218b based on an instruction from the controller 281.

The substrate mounting table 212 is configured such that the substrate 200 placed on the substrate placing surface 211 can be elevated or lowered by operating the elevator 218 to elevate or lower the shaft 217 and the substrate mounting table 212. In addition, a bellows 219 covers a periphery of a lower end of the shaft 217 to maintain the process space (that is, the process chamber 202) airtight.

When the substrate 200 is transferred, the substrate mounting table 212 is lowered until the substrate placing surface 211 faces the substrate loading/unloading port 206, that is, until a transfer position of the substrate 200 is reached. When the substrate 200 is processed, the substrate mounting table 212 is elevated until the substrate 200 reaches a processing position in the process space (that is, the process chamber 202) as shown in FIG. 3.

A gas introduction hole 231 is provided at an upper portion (upstream side) of the process chamber 202. For example, the gas introduction hole 231 is provided in a ceiling of the vessel 203.

### <Atmosphere Regulator>

The gas introduction hole 231 is configured to communicate with a second gas supplier (which is a second gas supply structure) 230 capable of supplying a gas such as a process gas and the inert gas to the process chamber 202. For example, the second gas supplier 230 includes: a fourth gas supplier (which is a fourth gas supply structure) 240 and a fifth gas supplier (which is a fifth gas supply structure) 250 which are capable of supplying the process gas to the process chamber 202; and a sixth gas supplier (which is a sixth gas supply structure) 260 capable of supplying the inert gas to the process chamber 202. Although the gas introduction hole 231 alone is shown in FIG. 3, gas introduction holes may be provided for the gas suppliers mentioned above, respectively.

Further, the exhaust pipe 222 provided at the lower portion of the vessel 203 is configured to communicate with a second exhauster (which is a second exhaust structure) 220 capable of adjusting an atmosphere (inner atmosphere) of the process chamber 202.

A second atmosphere regulator (which is a second atmosphere adjusting structure) capable of adjusting the inner atmosphere of the process chamber 202 is configured to include the second gas supplier 230 and the second exhauster 220. Hereinafter, the fourth gas supplier 240, the fifth gas supplier 250 and the sixth gas supplier 260 (which are included in the second gas supplier 230) and the second exhauster 220 will be described in detail.

### <Fourth Gas Supplier>

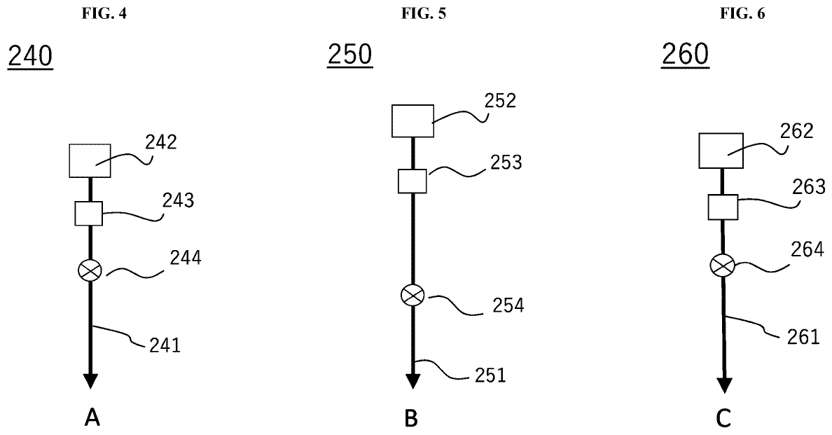

The fourth gas supplier 240 will be described with reference to FIG. 4. The fourth gas supplier 240 includes a fourth gas supply pipe 241. The fourth gas supply pipe 241 corresponds to “A” shown in FIG. 3, and is configured to supply the gas to the process chamber 202.

For example, a fourth gas source 242, an MFC 243 serving as a flow rate controller (flow rate control structure) and a valve 244 serving as an opening/closing valve are sequentially installed at the fourth gas supply pipe 241 in this order from an upstream side to a downstream side of the fourth gas supply pipe 241 in the gas flow direction.

The fourth gas source 242 is a source of a first gas (also referred to as a “first element-containing gas”) containing a first element. The first element-containing gas is a source gas, that is, one of process gases. In the present embodiments, for example, the first element is silicon (Si). That is, for example, the first element-containing gas is a silicon-containing gas. Specifically, for example, monosilane (SiH₄) gas may be used as the silicon-containing gas. When the SiH₄ gas is used, the SiH₄ gas is thermally decomposed to form a polysilicon film (which is a polycrystalline film) on the surface of the substrate 200.

The fourth gas supplier (also referred to as a “silicon-containing gas supplier” which is a silicon-containing gas supply structure) 240 is constituted mainly by the fourth gas supply pipe 241, the MFC 243 and the valve 244.

### <Fifth Gas Supplier>

Subsequently, the fifth gas supplier 250 will be described with reference to FIG. 5. The fifth gas supplier 250 includes a fifth gas supply pipe 251. The fifth gas supply pipe 251 corresponds to “B” shown in FIG. 3, and is configured to supply the gas to the process chamber 202.

For example, a fifth gas source 252, an MFC 253 serving as a flow rate controller (flow rate control structure) and a valve 254 serving as an opening/closing valve are sequentially installed at the fifth gas supply pipe 251 in this order from an upstream side to a downstream side of the fifth gas supply pipe 251 in the gas flow direction.

The fifth gas source 252 is a source of a second gas (also referred to as a “second element-containing gas”) containing a second element. The second element-containing gas is one of the process gases.

In the present embodiments, the second element-containing gas contains the second element different from the first element. For example, the second element is oxygen (O). In the present embodiments, for example, the second element-containing gas is described as an oxygen-containing gas. For example, the oxygen-containing gas is O₂.

The fifth gas supplier 250 is constituted mainly by the fifth gas supply pipe 251, the MFC 253 and the valve 254.

For example, when the film is formed on the substrate 200 using the first gas alone, the fifth gas supplier 250 may not be provided.

### <Sixth Gas Supplier>

The sixth gas supplier 260 will be described with reference to FIG. 6. The sixth gas supplier 260 includes a sixth gas supply pipe 261. The sixth gas supply pipe 261 corresponds to “C” shown in FIG. 3, and is configured to supply the gas to the process chamber 202.

For example, a sixth gas source 262, an MFC 263 serving as a flow rate controller (flow rate control structure) and a valve 264 serving as an opening/closing valve are sequentially installed at the sixth gas supply pipe 261 in this order from an upstream side to a downstream side of the sixth gas supply pipe 261 in the gas flow direction.

The sixth gas source 262 is a source of the inert gas. The inert gas is a gas used for exhausting an atmosphere (inner atmosphere) of the vessel 203, or a gas serving as a carrier gas for the first gas or the second gas. For example, the inert gas is the nitrogen (N₂) gas.

The sixth gas supplier 260 is constituted mainly by the sixth gas supply pipe 261, the MFC 263 and the valve 264.

The fourth gas supplier 240, the fifth gas supplier 250 and the sixth gas supplier 260 described above may also be collectively referred to as the “second gas supplier 230”.

### <Second Exhauster>

Subsequently, the second exhauster 220 shown in FIG. 3 will be described.

The exhaust pipe 222 is configured to be connected to the vessel 203 so as to communicate with the process space, that is, the process chamber 202. For example, an APC 223 serving as a pressure controller capable of controlling the inner pressure of the process chamber 202 to a predetermined pressure is provided at the exhaust pipe 222.

The APC 223 includes a valve body (not shown) whose opening degree is capable of being adjusted, and is configured to adjust a conductance of the exhaust pipe 222 in response to an instruction from the controller 281. In addition, a valve 224 is provided at the exhaust pipe 222 at a downstream side of the APC 223. The exhaust pipe 222, the valve 224 and the APC 223 may also be collectively referred to as the “second exhauster 220”.

In addition, a DP (Dry Pump) 225 is provided at a downstream side of the exhaust pipe 222. The DP 225 is configured to exhaust the inner atmosphere of the process chamber 202 via the exhaust pipe 222.

### (3) Configuration of Controller

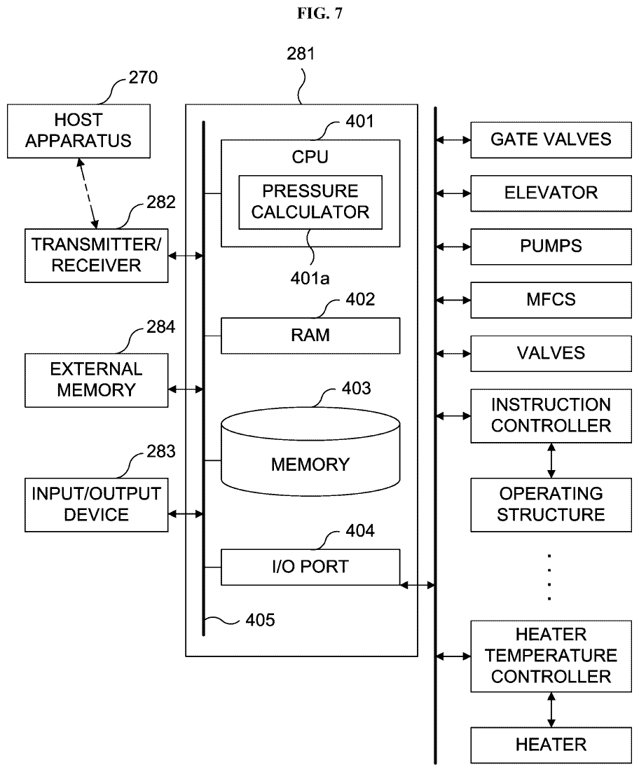

Subsequently, the controller 281 will be described with reference to FIG. 7.

The controller 281 serving as the control structure (control apparatus) is constituted by a computer including the CPU (Central Processing Unit) 401, the RAM (Random Access Memory) 402, a memory 403 serving as a storage and an I/O port 404. The RAM 402, the memory 403 and the I/O port 404 is configured to be capable of exchanging data with the CPU 401 via an internal bus 405.

A network transmitter/receiver 282 connected to a host apparatus 270 via a network is provided. For example, the network transmitter/receiver 282 is capable of receiving data such as information regarding a processing history and a processing schedule for the substrate 200 in a lot from the host apparatus 270.

For example, the memory 403 may be embodied by a component such as a flash memory and a HDD (Hard Disk Drive). For example, a process recipe in which information such as procedures and conditions of a substrate processing is stored or a control program for controlling the operations of the substrate processing apparatus may be readably stored in the memory 403.

The process recipe is obtained by combining procedures (steps) of the substrate processing described later such that the controller 281 can execute the steps to acquire a predetermined result, and functions as a program. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 402 serves as a memory area (work area) in which the program or the data read by the CPU 401 is temporarily stored.

The I/O port 404 is electrically connected to the components of the substrate processing apparatus described above, such as the gate valve 205, the elevator 218, the pressure controllers (that is, the APCs) mentioned above, the pumps (that is, the DPs) mentioned above and the heater controller 216.

The CPU 401 is configured to read and execute the control program from the memory 403, and is configured to read the process recipe from the memory 403 in accordance with an instruction such as an operation command inputted from an input/output device 283. The CPU 401 is further configured to be capable of controlling various operations, in accordance with the read process recipe, such as an opening and closing operation of the gate valve 205, an elevating and lowering operation of the elevator 218, an on/off control operation of the heater controller 216, on/off control operations of the pumps mentioned above, flow rate adjusting operations of the MFCs mentioned above and opening and closing operations of the valves mentioned above.

In addition, by executing the control program read from the memory 403, the CPU 401 functions as a pressure calculator (which is a pressure calculating structure) 401a capable of calculating a pressure difference between the vacuum transfer chamber 103 and the process chamber 202. The pressure calculator 401a is configured to calculate the pressure difference between the vacuum transfer chamber 103 and the process chamber 202 based on the pressure measurement result measured by the first pressure meter 179 and the pressure measurement result measured by the second pressure meter 226.

The controller 281 according to the present embodiments may be embodied by preparing an external memory 284 (for example, a magnetic disk such as a hard disk, an optical disk such as a DVD, a magneto-optical disk such as an MO, a semiconductor memory such as a USB memory) storing the program mentioned above and by installing the program onto the computer by using the external memory 284. Further, a method of providing the program to the computer is not limited to the external memory 284. For example, the program may be directly provided to the computer by a communication interface such as the Internet and a dedicated line instead of the external memory 284. Further, the memory 403 and the external memory 284 may be embodied by a non-transitory computer-readable recording medium. Hereinafter, the memory 403 and the external memory 284 may be collectively or individually referred to as a “recording medium”. In the present specification, the term “recording medium” may refer to the memory 403 alone, may refer to the external memory 284 alone, or may refer to both of the memory 403 and the external memory 284.

### (4) Substrate Processing

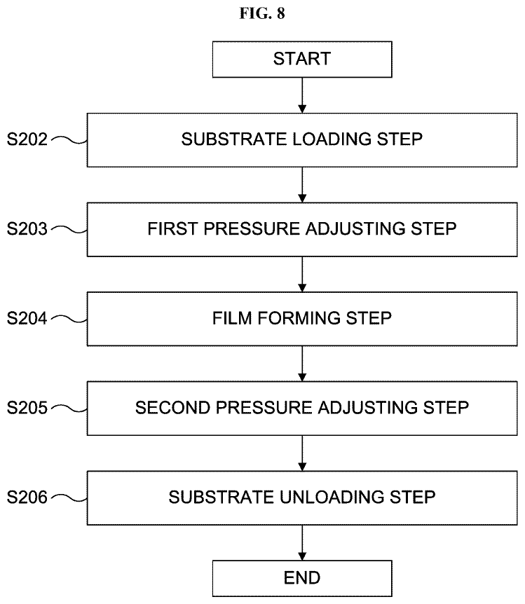

Hereinafter, as a part of the manufacturing process of the semiconductor device (that is, the substrate processing described above), the film forming process of forming a film on the substrate 200 by using the substrate processing apparatus mentioned above will be described with reference to FIG. 8. In the description, the controller 281 controls the operations of the components constituting the substrate processing apparatus.

### <Substrate Loading Step S202>

A substrate loading step S202 will be described. In the present step, the substrate 200 in stand-by in the vacuum transfer chamber 103 is loaded (transferred) into the process chamber 202 of the process module 201.

Specifically, the substrate mounting table 212 is lowered to the transfer position (substrate transfer position) of the substrate 200 such that the lift pins 207 penetrate through the through-holes 214 of the substrate mounting table 212. As a result, the lift pins 207 protrude from a surface of the substrate mounting table 212 by a predetermined height.

Subsequently, the gate valve 205 is opened to communicate the transfer space 202A with the vacuum transfer chamber 103 adjacent to the transfer space 202A. Then, the substrate 200 is placed on and supported by the lift pins 207 by the vacuum transfer robot 112.

After the substrate 200 is placed on the lift pins 207, by elevating the substrate mounting table 212, the substrate 200 is placed on and supported by the substrate placing surface 211, and the substrate mounting table 212 is elevated to a substrate processing position (that is, the processing position) as shown in FIG. 3.

### <First Pressure Adjusting Step S203>

A first pressure adjusting step S203 will be described. In the present step, the inner pressure of the process chamber 202 is adjusted to a substrate processing pressure.

Specifically, when the substrate mounting table 212 is elevated to the substrate processing position, the inner atmosphere of the process chamber 202 is exhausted from the process chamber 202 via the exhaust pipe 222, and the inner pressure of the process chamber 202 is adjusted such that the inner pressure of the process chamber 202 reaches the substrate processing pressure (which is predetermined).

A pressure adjustment in the first pressure adjusting step S203 will be described in detail later.

### <Film Forming Step S204>

Subsequently, a film forming step S204 will be described.

In the present step, the substrate 200 is heated by the heater 213 while placed on the substrate placing surface 211. While adjusting the inner pressure of the process chamber 202 to a predetermined substrate processing pressure, when a temperature of the substrate 200 reaches a predetermined temperature (for example, within a range from 400° C. to 600° C.), the process gas is supplied via the gas suppliers mentioned above onto the substrate 200 to form a predetermined film.

For example, a first gas supply step of supplying the source gas (which is the first element-containing gas) onto the substrate 200 and a second gas supply step of supplying a reactive gas (which is the second element-containing gas) onto the substrate 200 are repeatedly performed a predetermined number of times.

In a manner described above, in the film forming step S204, for example, the silicon-containing gas serving as the first element-containing gas is supplied onto the substrate 200 to form a silicon-containing film on the substrate 200. When forming the silicon-containing film, the oxygen-containing gas may be further supplied to form a silicon oxide film (SiO film).

### <Second Pressure Adjusting Step S205>

A second pressure adjusting step S205 will be described. In the present step, after the film forming step S204 in which the film is formed on the substrate 200, the inner pressure of the process chamber 202 is adjusted to a substrate transfer pressure.

Specifically, for example, after the first gas supply step and the second gas supply step are repeatedly performed the predetermined number of times to form the film of a desired thickness, the inner atmosphere of the process chamber 202 is exhausted from the process chamber 202 via the exhaust pipe 222, and the inner pressure of the process chamber 202 is adjusted such that the inner pressure of the process chamber 202 reaches the substrate transfer pressure (which is predetermined).

A pressure adjustment in the second pressure adjusting step S205 will be described in detail later.

### <Substrate Unloading Step S206>

Subsequently, a substrate unloading step S206 will be described. In the present step, after adjusting the inner pressure of the process chamber 202 to the substrate transfer pressure (which is predetermined), the substrate mounting table 212 is lowered and moved to the transfer position. After the substrate 200 is moved to the transfer position, the gate valve 205 is opened, and the substrate 200 is unloaded (transferred) from the transfer space 202A to the vacuum transfer chamber 103.

### (5) Atmosphere Control

Subsequently, an atmosphere control in each of the steps S202 to S206 mentioned above will be described. In addition, in the following description, an operation for the atmosphere control is also controlled by the controller 281.

In the substrate loading step S202 and the substrate unloading step S206, the substrate 200 is loaded and unloaded between the vacuum transfer chamber 103 and the process chamber 202 of the process module 201. When the substrate 200 is loaded or unloaded, in the vacuum transfer chamber 103, in order to prevent a contamination due to an atmospheric diffusion from the process chamber 202, the inert gas is supplied into the vacuum transfer chamber 103 via the first gas supplier 170a of the first atmosphere regulator 170, and thereby it is possible to maintain a positive pressure state in which the inner pressure of the vacuum transfer chamber 103 is higher than the inner pressure of the process chamber 202.

However, when the inert gas is constantly supplied, there is a risk that the inert gas will be consumed in a large amount. In particular, since a volume of the vacuum transfer chamber 103 is greater than a volume of the process chamber 202, such a risk is high.

Therefore, in the present embodiments, the atmosphere control described below is performed.

### <Outline of Atmosphere Control>

According to the present embodiments, the atmosphere control is performed by performing one or more of the following (i) to (iv) while maintaining the inner pressure of the vacuum transfer chamber 103 to be higher than the inner pressure of the process chamber 202.

(i) An amount (hereinafter, also referred to as a “gas supply amount”) of the gas supplied into the vacuum transfer chamber 103 is set such that the gas supply amount when the substrate 200 is loaded or unloaded is greater than the gas supply amount when the substrate 200 is processed. The term “when the substrate 200 is loaded or unloaded” refers to a time when a moving step of moving the substrate 200 between the vacuum transfer chamber 103 and the process chamber 202 is performed, that is, for example, when the substrate 200 is loaded in the substrate loading step S202 or when the substrate 200 is unloaded in the substrate unloading step S206. In addition, the term “when the substrate 200 is processed” refers to a time when a processing step of processing the substrate 200 is performed in the process chamber 202, that is, for example, when the film is formed in the film forming step S204.

(ii) A gas supply control of the gas with respect to the vacuum transfer chamber 103 is performed such that a supply of the gas is stopped when the substrate 200 is processed or when the apparatus (that is, the substrate processing apparatus) is in stand-by, or such that the gas supply amount when the substrate 200 is processed is smaller than the gas supply amount when the substrate 200 is loaded or unloaded. The term “when the apparatus is in stand-by” refers to a time when a stand-by step (waiting step) during which the substrate 200 is not processed in the process chamber 202 is performed, that is, for example, when each of the steps S202 to S206 is not performed.

(iii) A gas exhaust control of the gas with respect to the vacuum transfer chamber 103 is performed such that an exhaust of the gas is stopped when the substrate 200 is processed or when the apparatus is in stand-by, or such that an exhaust amount (hereinafter, also referred to as a “gas exhaust amount”) of the gas when the substrate 200 is processed is smaller than the gas exhaust amount when the substrate 200 is loaded or unloaded.

(iv) A gas supply and exhaust control of the gas with respect to the vacuum transfer chamber 103 is performed such that the supply of the gas and the exhaust of the gas are stopped when the substrate 200 is processed or when the apparatus is in stand-by. By stopping the supply of the gas and the exhaust of the gas as described above, the inner atmosphere of the vacuum transfer chamber 103 remains unexhausted within the vacuum transfer chamber 103.

By performing one or more of (i) to (iv) mentioned above or by performing an appropriate combination of (i) to (iv) mentioned above, it is possible to reduce the supply of the gas to the vacuum transfer chamber 103. Thereby, it is possible to reduce a consumption amount of the gas (that is, inert gas) as compared with a case where the gas is supplied constantly.

### <Example of Process Flow of Atmosphere Control>

Hereinafter, an example of the atmosphere control mentioned above will be described in more detail by applying the atmosphere control to each of the steps S202 to S206.

In the substrate loading step S202, the substrate 200 to be processed is loaded from the vacuum transfer chamber 103 into the process chamber 202 of the process module 201. After the substrate 200 is loaded, the gate valve 205 between the vacuum transfer chamber 103 and the process module 201 is closed.

Thereafter, in the first pressure adjusting step S203, the inner pressure of the vacuum transfer chamber 103 is adjusted to be higher than the inner pressure of the process chamber 202, and such a state is maintained. In such a state, the inner pressure of the process chamber 202 is set to a substrate processing pressure PP1 (which is predetermined). Therefore, the inner pressure of the vacuum transfer chamber 103 is set to a pressure PW1 which is higher than the substrate processing pressure PP1.

In the film forming step S204, the film is formed on the substrate 200. When forming the film, the inner pressure of the process chamber 202 is maintained at the substrate processing pressure PP1. Meanwhile, for a pressure control inside the vacuum transfer chamber 103, the supply of the gas and the exhaust of the gas inside the vacuum transfer chamber 103 are stopped while maintaining the inner pressure of the vacuum transfer chamber 103 to be higher than the inner pressure of the process chamber 202. Alternatively, the supply of the gas and the exhaust of the gas are not stopped, and the gas supply amount and the gas exhaust amount inside the vacuum transfer chamber 103 are reduced to an extent such that it is possible to maintain the inner pressure of the vacuum transfer chamber 103 to be higher than the inner pressure of the process chamber 202.

After the film is formed on the substrate 200, in the second pressure adjusting step S205, the inner pressure of the process chamber 202 is adjusted to a substrate transfer pressure PP3 (which is predetermined). When adjusting the inner pressure of the process chamber 202, regarding the inner pressure of the vacuum transfer chamber 103 and the inner pressure of the process chamber 202, the supply of the gas and the exhaust of the gas inside the vacuum transfer chamber 103 are resumed to adjust the inner pressure of the vacuum transfer chamber 103 to a pressure PW2 which is higher than the substrate transfer pressure PP3. Thereby, it is possible to maintain the inner pressure of the vacuum transfer chamber 103 to be higher than the inner pressure of the process chamber 202. For example, maintaining such a state may be achieved by supplying the inert gas into the vacuum transfer chamber 103 or by using both of the first gas supplier 170a and the first exhauster 170b (that is, by both of the supply of the gas and the exhaust of the gas).

Then, in the substrate unloading step S206, the gate valve 205 between the vacuum transfer chamber 103 and the process module 201 is opened, and the substrate (which is processed) 200 is unloaded from the process module 201 to the vacuum transfer chamber 103. Thereby, a series of the substrate processing for the substrate 200 is completed.

A state in which the inner pressure of the vacuum transfer chamber 103 is higher than the inner pressure of the process chamber 202 can be maintained by performing the atmosphere control mentioned above. Thereby, it is possible to prevent the contamination of the vacuum transfer chamber 103 due to the atmospheric diffusion from the process chamber 202. In addition, while preventing the contamination from the process chamber 202, it is possible to reduce the amount of the gas supplied into the vacuum transfer chamber 103. Thereby, it is possible to reduce the consumption amount of the gas as compared with the case where the gas is supplied constantly.

### <Specific Examples of Atmosphere Control>

Subsequently, the atmosphere control according to the present embodiments will be described in more detail by using specific examples. In the present embodiments, the specific examples will be described in order from a first aspect to a twentieth aspect.

### <First Aspect>

The first aspect corresponds to a basic processing aspect of the atmosphere control in the present embodiments.

The substrate processing (which includes the steps S202 to S206 mentioned above) can be classified into the following steps (a) to (c) when focusing on the substrate 200.
Step (a): the moving step of moving the substrate 200 between the vacuum transfer chamber 103 and the process chamber 202;
Step (b): the processing step of processing the substrate 200 in the process chamber 202; and
Step (c): the stand-by step (waiting step) in which the substrate 200 is not processed in the process chamber 202.

When each of the steps (a) to (c) is included in the substrate processing, the following control process is performed as the atmosphere control according to the first aspect. Specifically, while maintaining the inner pressure of the vacuum transfer chamber 103 to be higher than the inner pressure of the process chamber 202, the amount of the gas supplied into the vacuum transfer chamber 103 is reduced in the “processing step” or in the “stand-by step” as compared with the “moving step”. The term “the amount of the gas is reduced” mentioned above may also refer to a case where the gas is not supplied (that is, the supply of the gas is stopped).

That is, as the atmosphere control according to the first aspect, there is provided a technique that includes: the process chamber 202 in which the substrate 200 is processed; the vacuum transfer chamber 103 capable of communicating with the process chamber 202; the first atmosphere regulator 170 including the first gas supplier 170a capable of supplying the inert gas to the vacuum transfer chamber 103 and the first exhauster 170b capable of exhausting the inner atmosphere of the vacuum transfer chamber 103; the second atmosphere regulator including the second gas supplier 230 capable of supplying the process gas to the process chamber 202 and the second exhauster 220 capable of adjusting the inner atmosphere of the process chamber 202; and the controller 281 configured to be capable of controlling an amount (supply amount) of the inert gas supplied into the vacuum transfer chamber 103 in a state where the inner pressure of the vacuum transfer chamber 103 is higher than the inner pressure of the process chamber 202 such that the supply amount of the inert gas in the step (a) is greater than that in the step (b), the supply amount of the inert gas in the step (a) is greater than that in the step (c), or the supply amount of the inert gas in the step (a) is greater than those in both of the step (b) and the step (c).

By performing such an atmosphere control in the present aspect, it is possible to prevent the inner atmosphere of the process chamber 202 from flowing into (or entering) the vacuum transfer chamber 103. For example, the gases and particles used in the substrate processing may remain in the process chamber 202 after the processing step has been performed. Thus, when the gases or the particles flow into the vacuum transfer chamber 103, the gases or the particles may adhere to an inner wall of the vacuum transfer chamber 103 or the substrate 200 in the vacuum transfer chamber 103. However, by performing the atmosphere control according to the first aspect, it is possible to set the inner pressure of the vacuum transfer chamber 103 to be higher than the inner pressure of the process chamber 202. As a result, it is possible to prevent the inner atmosphere of the process chamber 202 from flowing into the vacuum transfer chamber 103.

In addition, by performing the atmosphere control according to the first aspect, while preventing the inner atmosphere of the process chamber 202 from flowing into the vacuum transfer chamber 103, it is also possible to reduce the amount of the inert gas supplied into the vacuum transfer chamber 103 as compared with the case where the inert gas is supplied constantly (that is, a case where the inert gas is continuously flowing into the vacuum transfer chamber 103).

The atmosphere control according to the present aspect is particularly useful in a case where the process chambers 202a to 202d are provided and different gases are used in each of the process chambers 202a to 202d.

### <Second Aspect>

In a second aspect, in addition to the first aspect mentioned above, the supply of the gas and the exhaust of the gas are stopped to control the inner atmosphere of the vacuum transfer chamber 103 to remain unexhausted within the vacuum transfer chamber 103.

Specifically, as the atmosphere control according to the second aspect, in the step (b) or the step (c) mentioned above, there is provided a technique that includes: one or more of stopping a supply of the inert gas from the first gas supplier 170a to the vacuum transfer chamber 103 and stopping an exhaust of the inner atmosphere of the vacuum transfer chamber 103 by the first exhauster 170b. In other words, as the atmosphere control according to the second aspect, stopping the supply of the inert gas may be performed, stopping the exhaust of the inner atmosphere of the vacuum transfer chamber 103 may be performed, or both of stopping the supply of the inert gas and stopping the exhaust of the inner atmosphere of the vacuum transfer chamber 103 may be performed.

According to such an atmosphere control in the present aspect, by stopping the supply of the inert gas, it is possible to more reliably reduce the amount of the inert gas supplied into the vacuum transfer chamber 103. In addition, by stopping the exhaust of the inner atmosphere of the vacuum transfer chamber 103, it is possible to reliably maintain a state in which the inner pressure of the vacuum transfer chamber 103 is higher than the inner pressure of the process chamber 202.

### <Third Aspect>

In a third aspect, when both of the supply of the inert gas and the exhaust of the inner atmosphere are stopped as described in the second aspect mentioned above, the supply of the inert gas and the exhaust of the inner atmosphere are performed with a predetermined time difference rather than simultaneously.

Specifically, as the atmosphere control according to the third aspect, in the step (b) or the step (c) mentioned above, there is provided a technique that includes: stopping the supply of the inert gas from the first gas supplier 170a to the vacuum transfer chamber 103 and stopping the exhaust of the inner atmosphere of the vacuum transfer chamber 103 with the predetermined time difference. It is preferable that the predetermined time difference is set in advance. Further, the predetermined time difference is not particularly limited as long as it is within a period of the step (b) or the step (c). In addition, as long as stopping the supply of the inert gas and stopping the exhaust of the inner atmosphere of the vacuum transfer chamber 103 are performed with the predetermined time difference rather than simultaneously, there is no limitation as to which of them is performed first.

When both of stopping the supply of the inert gas and stopping the exhaust of the inner atmosphere of the vacuum transfer chamber 103 are performed, in a case where they are performed simultaneously, the inner atmosphere of the vacuum transfer chamber 103 may be disturbed. As a result, the particles in the vacuum transfer chamber 103 may fly up. In contrast, by performing such an atmosphere control in the third aspect, by performing each of stopping the supply of the inert gas and stopping the exhaust of the inner atmosphere of the vacuum transfer chamber 103 with the predetermined time difference, it is possible to prevent (or suppress) the particles from flying up in the vacuum transfer chamber 103. Thus, the atmosphere control according to the present aspect is particularly useful in preventing foreign substances (that is, the particles) from flowing into the vacuum transfer chamber 103.

### <Fourth Aspect>

In a fourth aspect, the predetermined time difference in the third aspect mentioned above will be specifically defined.

That is, as the atmosphere control according to the fourth aspect, there is provided a technique where the predetermined time difference is a time duration in which the inner pressure of the vacuum transfer chamber 103 is capable of being maintained higher than the inner pressure of the process chamber 202. For example, the predetermined time difference can be obtained in advance based on information such as the volume of the vacuum transfer chamber 103, the inner pressure of the process chamber 202 during the processing step and a processing capacity of each of the first gas supplier 170a and the first exhauster 170b.

According to such an atmosphere control in the present aspect, by specifically defining the predetermined time difference, it is possible to reliably maintain the state in which the inner pressure of the vacuum transfer chamber 103 is higher than the inner pressure of the process chamber 202. Thus, the atmosphere control according to the present aspect is particularly useful in preventing the foreign substances from flowing into the vacuum transfer chamber 103.

### <Fifth Aspect>

In a fifth aspect, in addition to the first aspect mentioned above, when exhausting the inner atmosphere of the vacuum transfer chamber 103, the exhaust control is performed as described below.

Specifically, as the atmosphere control according to the fifth aspect, there is provided a technique where an amount (exhaust amount) of the inner atmosphere exhausted from the vacuum transfer chamber 103 is set such that the exhaust amount in the step (a) is smaller than that in the step (b), the exhaust amount in the step (a) is smaller than that in the step (c), or the exhaust amount in the step (a) is smaller than those in the step (b) and in the step (c). In other words, when exhausting the inner atmosphere of the vacuum transfer chamber 103, the amount of the inner atmosphere exhausted in the step (a) may be set to be smaller than the amount of the inner atmosphere exhausted in the step (b), may be set to be smaller than the amount of the inner atmosphere exhausted in the step (c), or may be set to be smaller than the amount of the inner atmosphere exhausted in each of the steps (b) and (c). The term “the amount of the gas is reduced” mentioned above may also refer to a case where the inner atmosphere remains unexhausted (that is, the exhaust amount is zero (0)).

According to such an atmosphere control in the present aspect, it is possible to reliably maintain the state in which the inner pressure of the vacuum transfer chamber 103 is higher than the inner pressure of the process chamber 202. Thus, the atmosphere control according to the present aspect is particularly useful in preventing the foreign substances from flowing into the vacuum transfer chamber 103.

### <Sixth Aspect>

In a sixth aspect, in addition to the first aspect mentioned above, the following control process is performed as the atmosphere control according to the sixth aspect by focusing on a difference (pressure difference) between the inner pressure of the vacuum transfer chamber 103 and the inner pressure of the process chamber 202.

Specifically, as the atmosphere control according to the sixth aspect, there is provided a technique where the first atmosphere regulator 170 increases the inner pressure of the vacuum transfer chamber 103 when the pressure difference between the inner pressure of the vacuum transfer chamber 103 and the inner pressure of the process chamber 202 exceeds a first threshold value.

The first threshold value is set in advance to be a value slightly smaller than the pressure difference between the vacuum transfer chamber 103 and the process chamber 202, which is a value at which it is possible to prevent the inner atmosphere of the process chamber 202 from flowing into the vacuum transfer chamber 103. In addition, the first threshold value is set in advance to be a value slightly smaller than a limit value described later.

For example, even when the inner pressure of the process chamber 202 is higher than the inner pressure of the vacuum transfer chamber 103 by an amount corresponding to the first threshold value, depending on the gate valve 205 or a seal structure around the gate valve 205, the inner atmosphere of the process chamber 202 may not move into the vacuum transfer chamber 103. However, when the pressure difference between the inner pressure of the vacuum transfer chamber 103 and the inner pressure of the process chamber 202 exceeds the first threshold value to some extent, such as when the inner pressure of the process chamber 202 is significantly higher than the inner pressure of the vacuum transfer chamber 103, the limit value of a hardware configuration such as the gate valve 205 may be exceeded. In such a case, the inner atmosphere of the process chamber 202 may flow into the vacuum transfer chamber 103.

In order to avoid such a situation, the first threshold value is set in the atmosphere control according to the sixth aspect. Then, when the pressure difference between the inner pressure of the vacuum transfer chamber 103 and the inner pressure of the process chamber 202 exceeds the first threshold value, the inner pressure of the vacuum transfer chamber 103 is increased to reduce the pressure difference.

According to such an atmosphere control in the present aspect, when there is a risk that the inner atmosphere of the process chamber 202 will flow into the vacuum transfer chamber 103 based on the first threshold value (which is set in advance), by increasing the inner pressure of the vacuum transfer chamber 103 to reduce the pressure difference, it is possible to prevent such a risk. Thus, the atmosphere control according to the present aspect is particularly useful in preventing the foreign substances from flowing into the vacuum transfer chamber 103.

The first threshold value may be set in consideration of parameters such as a hardware configuration of the gate valve 205, hardware configurations around the gate valve 205, the process conditions and usage states of components, and is not limited to a specific value as long as it can prevent the risk that the inner atmosphere flows into the vacuum transfer chamber 103. This is thought to be because conditions related to the pressure difference between the process chamber 202 and the vacuum transfer chamber 103 change depending on the parameters such as the hardware configuration of the gate valve 205, the hardware configurations around the gate valve 205, the process conditions and the usage states of the components.

### <Seventh Aspect>

In a seventh aspect, the atmosphere control according to the sixth aspect mentioned above will be specifically defined.

That is, as the atmosphere control according to the seventh aspect, there is provided a technique where the first gas supplier 170a supplies the inert gas into the vacuum transfer chamber 103 when the pressure difference between the inner pressure of the vacuum transfer chamber 103 and the inner pressure of the process chamber 202 exceeds the first threshold value. In the present aspect, the supply mount of the inert gas is set such that the exhaust amount of the inner atmosphere of the vacuum transfer chamber 103 is smaller than the amount of the inert gas supplied into the vacuum transfer chamber 103.

According to such an atmosphere control in the present aspect, by supplying the inert gas into the vacuum transfer chamber 103, it is possible to increase the inner pressure of the vacuum transfer chamber 103. Thereby, it is possible to prevent the risk that the inner atmosphere of the process chamber 202 will flow into the vacuum transfer chamber 103. Thus, the atmosphere control according to the present aspect is particularly useful in preventing the foreign substances from flowing into the vacuum transfer chamber 103.

### <Eighth Aspect>

In an eighth aspect, similar to the seventh aspect mentioned above, the atmosphere control according to the sixth aspect mentioned above will be more specifically defined.

That is, as the atmosphere control according to the eighth aspect, there is provided a technique where the first exhauster 170b stops the exhaust of the inner atmosphere of the vacuum transfer chamber 103 or reduces the exhaust amount of the inner atmosphere of the vacuum transfer chamber 103 when the pressure difference between the inner pressure of the vacuum transfer chamber 103 and the inner pressure of the process chamber 202 exceeds the first threshold value.

According to such an atmosphere control in the present aspect, by stopping the exhaust of the inner atmosphere of the vacuum transfer chamber 103 or by reducing the exhaust amount of the inner atmosphere of the vacuum transfer chamber 103, it is possible to increase the inner pressure of the vacuum transfer chamber 103. Thereby, it is possible to prevent the risk that the inner atmosphere of the process chamber 202 will flow into the vacuum transfer chamber 103. Thus, the atmosphere control according to the present aspect is particularly useful in preventing the foreign substances from flowing into the vacuum transfer chamber 103.

### <Ninth Aspect>

In a ninth aspect, similar to the seventh aspect mentioned above, the atmosphere control according to the sixth aspect mentioned above will be more specifically defined.

That is, as the atmosphere control according to the ninth aspect, there is provided a technique where the inert gas is supplied into the vacuum transfer chamber 103 when the pressure difference between the inner pressure of the vacuum transfer chamber 103 and the inner pressure of the process chamber 202 exceeds the first threshold value and where the supply of the inert gas is stopped when the pressure difference is lower than the first threshold value.

According to such an atmosphere control in the present aspect, while preventing the risk that the inner atmosphere of the process chamber 202 will flow into the vacuum transfer chamber 103 based on the first threshold value, it is possible to more reliably reduce the amount of the inert gas supplied into the vacuum transfer chamber 103 by stopping the supply of the inert gas when the risk is eliminated.

### <Tenth Aspect>

In a tenth aspect, a recognition control of the pressure difference in the sixth aspect mentioned above will be specifically defined.

As described above, the CPU 401 in the controller 281 serving as the control structure (control apparatus) functions as the pressure calculator 401a by executing the control program read from the memory 403. In other words, as a function of the control structure, the pressure calculator 401a capable of calculating the pressure difference between the process chamber 202 and the vacuum transfer chamber 103 is provided.

The pressure measurement result measured by the first pressure meter 179 capable of measuring the inner pressure of the vacuum transfer chamber 103 and the pressure measurement result measured by the second pressure meter 226 capable of measuring the inner pressure of the process chamber 202 are respectively output to the pressure calculator 401a. Then, the pressure calculator 401a calculates the pressure difference between the vacuum transfer chamber 103 and the process chamber 202 based on the pressure measurement results from the first pressure meter 179 and the second pressure meter 226. Hereinafter, the first pressure meter 179 and the second pressure meter 226 may also be collectively or individually referred to simply as a “pressure meter”. The pressure calculator 401a then calculates the pressure difference between the inner pressure of the process chamber 202 and the inner pressure of the vacuum transfer chamber 103 based on pressure values measured by the pressure meter.

According to such an atmosphere control in the present aspect, the pressure calculator 401a can calculate the pressure difference between the process chamber 202 and the vacuum transfer chamber 103 in real time based on the pressure values measured by the pressure meter. In other words, it is possible to monitor the pressure difference between the process chamber 202 and the vacuum transfer chamber 103.

Therefore, as described in the sixth aspect mentioned above, when controlling whether to increase the inner pressure of the vacuum transfer chamber 103 based on the first threshold value, such a pressure control can be performed while quickly responding to a change in the pressure difference (that is, for example, without delay when the pressure difference exceeds the first threshold value). In addition, it is possible to perform the pressure control more accurately.

### <Eleventh Aspect>

In an eleventh aspect, in addition to the first aspect mentioned above, the atmosphere control for the vacuum transfer chamber 103 and the process chamber 202 is performed in synchronization with a pressure fluctuation of the process chamber 202.

As described above, in the process chamber 202, the following steps are performed when the substrate processing is performed. That is, after the substrate 200 is loaded into the process chamber 202, the following steps are performed in this order: the first pressure adjusting step S203 of adjusting the inner pressure of the process chamber 202 to the substrate processing pressure; the processing step (for example, the film forming step S204) of supplying the process gas to the process chamber 202 to process the substrate 200; and the second pressure adjusting step S205 of adjusting the inner pressure of the process chamber 202 to the substrate transfer pressure after the processing step.

Under such a circumstance, as the atmosphere control according to the eleventh aspect, in the vacuum transfer chamber 103, the inner pressure of the vacuum transfer chamber 103 is adjusted in synchronization with at least one step among the steps described below. In other words, when the inner pressure of the process chamber 202 fluctuates in each step, the inner pressure of the vacuum transfer chamber 103 is adjusted in synchronization with such a pressure fluctuation. Specifically, as the atmosphere control according to the eleventh aspect, there is provided a technique where, after the substrate 200 is loaded into the process chamber 202, the first pressure adjusting step of adjusting the inner pressure of the process chamber 202 to the substrate processing pressure, the processing step of supplying the process gas to the process chamber 202 to process the substrate 200 and the second pressure adjusting step of adjusting the inner pressure of the process chamber 202 to the substrate transfer pressure after the processing step are performed, and wherein, in the vacuum transfer chamber 103, the inner pressure of the vacuum transfer chamber 103 is adjusted in synchronization with at least one step among the first pressure adjusting step, the processing step and the second pressure adjusting step.

According to such an atmosphere control in the present aspect, by synchronizing a pressure adjustment for the vacuum transfer chamber 103 with the pressure fluctuation in the process chamber 202, it is possible to reliably maintain the state in which the inner pressure of the vacuum transfer chamber 103 is higher than the inner pressure of the process chamber 202. Thus, the atmosphere control according to the present aspect is particularly useful in preventing the foreign substances from flowing into the vacuum transfer chamber 103.

### <Twelfth Aspect>

In a twelfth aspect, the step of the atmosphere control according to the eleventh aspect mentioned above is more specifically defined.

For example, when the processing step of processing the substrate 200 is the film forming step S204, in the film forming step S204, the first gas supply step of supplying the first element-containing gas (serving as the source gas) onto the substrate 200 and the second gas supply step of supplying the second element-containing gas (serving as the reactive gas) onto the substrate 200 are repeatedly performed the predetermined number of times. The first gas supply step may also be referred to as a “source gas supply step”, and the second gas supply step may also be referred to as a “reactive gas supply step”. The predetermined number of times is one or more times. A third gas supply step of supplying a third gas (for example, the inert gas) may be further performed between the first gas supply step and the second gas supply step.

Under such a circumstance, the inner pressure of the process chamber 202 may fluctuate between the first gas supply step and the second gas supply step.

Therefore, in the atmosphere control according to the twelfth aspect, in addition to the steps described in the eleventh aspect, the first gas supply step and the second gas supply step are included in the processing step, and the inner pressure of the vacuum transfer chamber 103 is adjusted in synchronization with at least one step among the first gas supply step and the second gas supply step. Specifically, as the atmosphere control according to the twelfth aspect, there is provided a technique where, in the substrate processing, the first gas supply step of supplying the source gas onto the substrate 200 and the second gas supply step of supplying the reactive gas onto the substrate 200 are repeatedly performed the predetermined number of times, and wherein, in the vacuum transfer chamber 103, the inner pressure of the vacuum transfer chamber 103 is adjusted in synchronization with at least one step among the first gas supply step and the second gas supply step.

According to such an atmosphere control in the present aspect, it is possible to more precisely synchronize the pressure adjustment for the vacuum transfer chamber 103 with the pressure fluctuation in the process chamber 202. Thereby, it is possible to reliably maintain the state in which the inner pressure of the vacuum transfer chamber 103 is higher than the inner pressure of the process chamber 202. Thus, the atmosphere control according to the present aspect is particularly useful in preventing the foreign substances from flowing into the vacuum transfer chamber 103.

### <Thirteenth Aspect>

In a thirteenth aspect, the pressure adjustment in each step of the atmosphere control according to the eleventh aspect or the twelfth aspect mentioned above is more specifically defined.

As described in the eleventh aspect or the twelfth aspect, the inner pressure of the process chamber 202 may fluctuate (vary) in each step. In consideration of such a fluctuation, in the atmosphere control according to the eleventh aspect or the twelfth aspect, the inner pressure of the vacuum transfer chamber 103 is adjusted in synchronization with at least one of the steps mentioned above.

However, the pressure control of adjusting the inner pressure of the vacuum transfer chamber 103 may not keep up with the pressure fluctuation in each step in the process chamber 202. For example, in the atmosphere control according to the eleventh aspect, when a process flow moves from the film forming step S204 (which is the processing step) to the second pressure adjusting S205, the inner pressure of the process chamber 202 may return to the substrate transfer pressure in the second pressure adjusting step S205 in “T seconds”. In such case, since a spatial volume of the vacuum transfer chamber 103 is greater than a spatial volume of the process chamber 202, it takes a pressure adjusting time of “T seconds plus several seconds” for the inner pressure of the vacuum transfer chamber 103 to be adjusted. When the inner pressure of the process chamber 202 is higher than the inner pressure of the vacuum transfer chamber 103 during the “several seconds” mentioned above, the inner atmosphere of the process chamber 202 may flow into the vacuum transfer chamber 103. In addition, for example, in the atmosphere control according to the twelfth aspect, the step in which the process gases are alternately supplied is included. However, when the first gas supply step and the second gas supply step are switched quickly, the pressure adjustment for the vacuum transfer chamber 103 may not be capable of keeping up with such quick transition. During a period in which the pressure adjustment for the vacuum transfer chamber 103 cannot keep up with such quick transition, when the inner pressure of the process chamber 202 is higher than the inner pressure of the vacuum transfer chamber 103, the inner atmosphere of the process chamber 202 may flow into the vacuum transfer chamber 103.

Therefore, in the atmosphere control according to the thirteenth aspect, in order to be capable of keeping up with the pressure fluctuation in the process chamber 202, the inner pressure of the vacuum transfer chamber 103 is adjusted to a pressure value set higher in consideration of the pressure fluctuation in the process chamber 202. In other words, as the atmosphere control according to the thirteenth aspect, there is provided a technique where the inner pressure of the vacuum transfer chamber 103 is adjusted to a pressure value (which is maintained to be higher than the inner pressure of the process chamber 202 even when the pressure fluctuation occurs in each step in the process chamber 202). More specifically, the pressure value is set to be higher, by a predetermined value, than the higher of the inner pressures of the process chamber 202 before and after the pressure fluctuation in the process chamber 202.

Specifically, for example, consider a case where the inner pressure PP1 of the process chamber 202 in the first pressure adjusting step S203 is 200 Pa, and the inner pressure PP2 of the process chamber 202 in the film forming step S204 performed thereafter is 100 Pa. In such a case, an inner pressure TP2 of the vacuum transfer chamber 103 in the film forming step S204 is adjusted to increase to 230 Pa, which is a pressure value set to be higher (by the predetermined value of 30 Pa) than 200 Pa (which is the higher of the inner pressures PP1 and PP2 before and after the pressure fluctuation in the process chamber 202). In addition, for example, consider a case where the inner pressure PP2 of the process chamber 202 in the film forming step S204 is 100 Pa, and the inner pressure PP3 of the process chamber 202 in the second pressure adjusting step S205 performed thereafter is 300 Pa. In such a case, an inner pressure TP3 of the vacuum transfer chamber 103 in the second pressure adjusting step S205 is adjusted in advance to increase to 330 Pa, which is a pressure value set to be higher (by the predetermined value of 30 Pa) than 300 Pa (which is the higher of the inner pressures PP2 and PP3 before and after the pressure fluctuation in the process chamber 202).

According to such an atmosphere control in the present aspect, by setting the inner pressure of the vacuum transfer chamber 103 higher than the higher of the pressures before and after the pressure fluctuation in the process chamber 202, it is possible to adjust the inner pressure of the vacuum transfer chamber 103 while quickly keeping up with (following) the pressure fluctuation in the process chamber 202. Therefore, when adjusting the inner pressure of the vacuum transfer chamber 103 in synchronization with at least one of the steps mentioned above, it is possible to prevent a situation in which the pressure adjustment for the vacuum transfer chamber 103 does not follow the pressure fluctuation in each step in the process chamber 202. As a result, it is possible to maintain the inner pressure of the vacuum transfer chamber 103 at a higher pressure than the inner pressure of the process chamber 202 even when the pressure fluctuation in the process chamber 202 occurs. Thus, the atmosphere control according to the present aspect is particularly useful in preventing the foreign substances from flowing into the vacuum transfer chamber 103.

### <Fourteenth Aspect>

In a fourteenth aspect, in addition to the first aspect mentioned above, the atmosphere control is also performed for the load lock chambers 122 and 123.

As described above, the load lock chambers 122 and 123 capable of communicating with the vacuum transfer chamber 103 are connected to the vacuum transfer chamber 103. Focusing on the load lock chambers 122 and 123, the following steps (d) and (e) are performed for the vacuum transfer chamber 103 and the load lock chambers 122 and 123 when transferring the substrate 200.

Step (d): a step of depressurizing the load lock chambers 122 and 123; and

Step (e): a moving step of moving the substrate 200 between the vacuum transfer chamber 103 and the load lock chambers 122 and 123.

When the steps (d) and (e) are included in the substrate processing, the following control process is performed as the atmosphere control according to the fourteenth aspect. Specifically, as the atmosphere control according to the fourteenth aspect, there is provided a technique in which the load lock chambers 122 and 123 capable of communicating with the vacuum transfer chamber 103 are provided, wherein the controller 281 is configured to be capable of controlling the amount (supply amount) of the inert gas supplied into the vacuum transfer chamber 103 in a state where the inner pressure of each of the load lock chambers 122 and 123 is higher than the inner pressure of the vacuum transfer chamber 103 such that the supply amount of the inert gas in the step (e) is greater than that in the step (d). In other words, the first atmosphere regulator 170 capable of adjusting the inner atmosphere of the vacuum transfer chamber 103 and the third atmosphere regulator 180 capable of adjusting the inner atmosphere of each of the load lock chambers 122 and 123 are respectively controlled to achieve such a relationship.

According to such an atmosphere control in the present aspect, similar to a relationship between the vacuum transfer chamber 103 and the process chamber 202, it is possible to prevent the inner atmosphere of the vacuum transfer chamber 103 from flowing into the load lock chambers 122 and 123. In other words, in a case where the vacuum transfer chamber 103 is adjacent to the load lock chambers 122 and 123, by preventing the inner atmosphere of the vacuum transfer chamber 103 from flowing into the load lock chambers 122 and 123, the atmosphere control according to the present aspect is particularly useful in preventing the foreign substances from flowing not only into the vacuum transfer chamber 103 but also into the load lock chambers 122 and 123. In addition, it is also possible to reduce the amount of the inert gas supplied into the vacuum transfer chamber 103.

### <Fifteenth Aspect>

In a fifteenth aspect, the atmosphere control according to the fourteenth aspect mentioned above will be more specifically defined.

In the step (d) mentioned above, the load lock chambers 122 and 123 are in a reduced pressure state. In consideration of such a state, as the atmosphere control according to the fifteenth aspect, there is provided a technique where the inner pressure of the vacuum transfer chamber 103 is controlled to be lower than the inner pressure of each of the load lock chambers 122 and 123 when the load lock chambers 122 and 123 are in the reduced pressure state.

According to such an atmosphere control in the present aspect, even when the load lock chambers 122 and 123 are in the reduced pressure state, it is possible to prevent the inner atmosphere of the vacuum transfer chamber 103 from flowing into the load lock chambers 122 and 123. Thus, the atmosphere control according to the present aspect is particularly useful in preventing foreign substances from flowing into the load lock chambers 122 and 123.

### <Sixteenth Aspect>

In a sixteenth aspect, the atmosphere control according to the fourteenth aspect mentioned above will be more specifically defined.

As the atmosphere control according to the sixteenth aspect, there is provided a technique where the inner pressure of the vacuum transfer chamber 103 is controlled to be lower than the inner pressure of each of the load lock chambers 122 and 123 and to be higher than the inner pressure of the process chamber 202 when the load lock chambers 122 and 123 are in the reduced pressure state.

According to such an atmosphere control in the present aspect, it is possible to prevent the inner atmosphere of the vacuum transfer chamber 103 from flowing into between the process chamber 202 and the vacuum transfer chamber 103 and between the vacuum transfer chamber 103 and the load lock chambers 123. Thus, the atmosphere control according to the present aspect is particularly useful in preventing foreign substances from flowing into the process chamber 202, the vacuum transfer chamber 103 and the load lock chambers 122 and 123.

### <Seventeenth Aspect>

In a seventeenth aspect, in addition to the first aspect mentioned above, an atmosphere control when the substrate 200 is unloaded from the process chamber 202 will be specifically defined.

Specifically, as the atmosphere control according to the seventeenth aspect, there is provided a technique where the inner pressure of the vacuum transfer chamber 103 is set to be equal to or higher than the inner pressure of the process chamber 202 when moving the substrate 200 from the vacuum transfer chamber 103 to the process chamber 202, and then the vacuum transfer chamber 103 and the process chamber 202 are in communication with each other such that the inner pressure of the vacuum transfer chamber 103 is higher than the inner pressure of the process chamber 202.

Regarding the inner pressure of the vacuum transfer chamber 103 and the inner pressure of the process chamber 202, basically by maintaining the relationship in which the inner pressure of the vacuum transfer chamber 103 is higher than the inner pressure of the process chamber 202, it is possible to prevent the inner atmosphere of the process chamber 202 from flowing into the vacuum transfer chamber 103. However, in a case where the pressure difference between the vacuum transfer chamber 103 and the process chamber 202 is large, at a timing when the gate valve 205 between the vacuum transfer chamber 103 and the process chamber 202 is opened, much of the inner atmosphere of the vacuum transfer chamber 103 may flow into the process chamber 202. In such a case, an unintended movement of the atmosphere may occur. As a result, for example, the inner atmosphere of the process chamber 202 may be scattered, or it may take time to adjust the inner pressure to the pressure for the substrate processing performed thereafter. In addition, since the inert gas may be used when adjusting the inner pressure, the inert gas may be consumed more.

In contrast, according to such an atmosphere control in the seventeenth aspect, by performing the atmosphere control in accordance with the timing at which the vacuum transfer chamber 103 and the process chamber 202 are in communication with each other, it is possible to prevent the pressure difference from becoming too large when the substrate 200 is unloaded from the process chamber 202. Therefore, by preventing the unintended movement of the atmosphere, it is possible to eliminate an occurrence of such situations mentioned above.

### <Eighteenth Aspect>

In an eighteenth aspect, in addition to the first aspect mentioned above, the operation of the gate valve 205 will be specifically defined.

That is, as an operation control (atmosphere control) according to the eighteenth aspect, there is provided a technique in which the substrate loading/unloading port 206 through which the vacuum transfer chamber 103 and the process chamber 202 are in communication with each other, and the gate valve 205 capable of opening and closing the substrate loading/unloading port 206 are provided, wherein the gate valve 205 is open in the step (a) and the gate valve 205 is closed in the step (b) or in the step (c).

According to such an operation control in the present aspect, by adjusting the inner atmosphere with the gate valve 205 closed in the step (b) or in the step (c), it is possible to reduce the amount of the gas (inert gas) supplied into the vacuum transfer chamber 103 while preventing the inner atmosphere of the process chamber 202 from flowing into the vacuum transfer chamber 103. For example, even when the supply amount of the inert gas is reduced with the gate valve 205 open, the inner pressure of the vacuum transfer chamber 103 and the inner pressure of the process chamber 202 will be eventually the same. Thereby, the inner atmosphere of the process chamber 202 may flow into the vacuum transfer chamber 103. However, by performing the operation control according to the eighteenth aspect, it is possible to eliminate an occurrence of such a situation mentioned above.

In addition, when the inner pressure of the process chamber 202 is higher than the inner pressure of the vacuum transfer chamber 103, even when the gate valve 205 is closed, the inner atmosphere of the process chamber 202 may flow into the vacuum transfer chamber 103. Therefore, even when the operation control according to the eighteenth aspect is performed, the relationship (that is, the inner pressure of the process chamber 202 is lower than the inner pressure of the vacuum transfer chamber 103) is maintained.

### <Nineteenth Aspect>

In a nineteenth aspect, the “stand-by step” described in the first aspect mentioned above will be specifically defined.

That is, as the atmosphere control according to the nineteenth aspect, there is provided a technique where the processing in the process chamber 202 is stopped during the stand-by step.

For example, the stand-by step may refer to an idling state. In the idling state, the inert gas may be supplied into the vacuum transfer chamber 103 or the process chamber 202 (in a state where the substrate 200 is not present).

By applying the atmosphere control in the first aspect mentioned above to the stand-by step as in the nineteenth aspect, it is possible to reduce the amount of the gas (inert gas) supplied into the vacuum transfer chamber 103 while preventing the inner atmosphere of the process chamber 202 from flowing into the vacuum transfer chamber 103.

### <Twentieth Aspect>

In a twentieth aspect, the atmosphere control described in the first aspect mentioned above will be more specifically defined.

That is, as the atmosphere control according to the twentieth aspect, there is provided a technique where the inner pressure of the vacuum transfer chamber 103 is adjusted by the first atmosphere regulator 170 and the inner pressure of the process chamber 202 is adjusted by the second atmosphere regulator.

According to such an atmosphere control in the present aspect, the first atmosphere regulator 170 adjusts the inner pressure of the vacuum transfer chamber 103, and the second atmosphere regulator adjusts the inner pressure of the process chamber 202. In such a case, for example, the pressure adjustment by the first atmosphere regulator 170 is performed by the first gas supplier 170a and the first exhauster 170b in cooperation. However, the present embodiments are not limited thereto. For example, the pressure adjustment by the first atmosphere regulator 170 may be performed by the first gas supplier 170a alone, or may be performed by the first exhauster 170b alone. The same may also be applied for the second atmosphere regulator. For example, the pressure adjustment by the second atmosphere regulator may be performed by the second gas supplier 230 and the second exhauster 220 in cooperation, may be performed by the second gas supplier 230 alone, or may be performed by the second exhauster 220 alone.

### <Twenty First Aspect)

In a twenty first aspect, a configuration of the second vessel described in the first aspect mentioned above is modified.

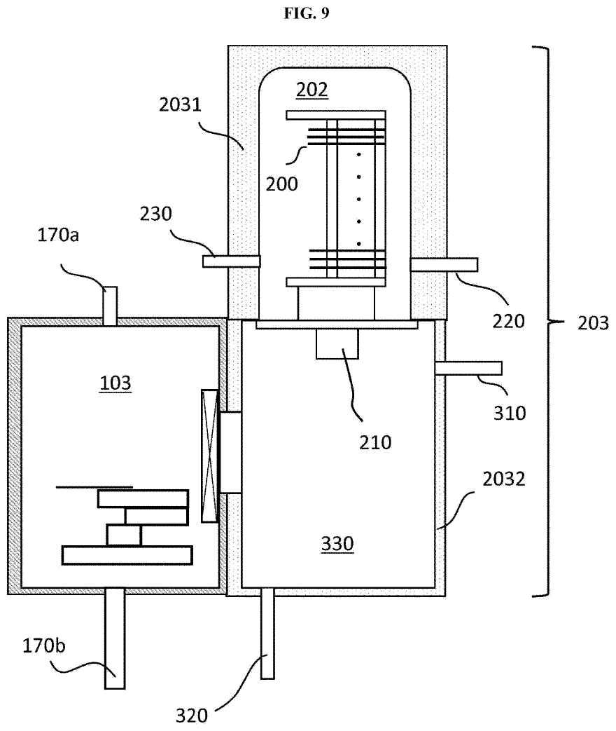

According to the twenty first aspect, as shown in FIG. 9, the process vessel 203 serving as the second vessel is configured to include an upper vessel 2031 including the process chamber 202 and a lower vessel 2032 adjacent to the upper vessel 2031 which includes a transfer chamber 330 communicating with the process chamber 202.

In such case, the transfer chamber 330 is provided with a seventh gas supplier (which is a seventh gas supply structure) 310 capable of supplying the gas to the transfer chamber 330 and a fourth exhauster (which is a fourth exhaust structure) 320 capable of exhausting the atmosphere (inner atmosphere) of the transfer chamber 330. In the present aspect, the seventh gas supplier 310 and the fourth exhauster 320 may be collectively referred to as the “second atmosphere regulator”. A pressure (inner pressure) of the transfer chamber 330 is adjusted by the second atmosphere regulator according to the present aspect.

In the present aspect, the substrate support 210 may be configured to be capable of supporting the plurality of substrates 200, and the plurality of substrates 200 may be processed collectively in the process chamber 202. The substrate support 210 according to the present aspect includes an elevator (which is an elevating structure) (not shown), and is configured to be capable of transferring (elevating or lowering) the plurality of substrates 200 between the process chamber 202 and the transfer chamber 330.

In the present aspect, the substrates 200 transferred to the process chamber 202 are processed by the process gas supplied from the second gas supplier 230.

According to such an atmosphere control in the present aspect, even when the substrate 200 is moved between the first vessel and the second vessel, specifically between the vacuum transfer chamber 103 and the transfer chamber 330 in the process vessel 203, by applying the atmosphere control mentioned above, it is possible to reduce the amount of the gas (inert gas) supplied into the vacuum transfer chamber 103 while preventing the inner atmosphere of the transfer chamber 330 from flowing into the vacuum transfer chamber 103.

### (6) Other Embodiments of Present Disclosure

While the technique of the present disclosure is described in detail by way of the embodiments mentioned above, the technique of the present disclosure is not limited thereto and may be modified in various ways without departing from the scope thereof.

For example, the embodiments mentioned above are described by way of an example in which two types of gases are supplied. However, the technique of the present disclosure is not limited thereto. For example, the film may be formed by supplying one type of gas or three or more types of gases.

For example, the embodiments mentioned above are described by way of an example in which the process vessels 203a to 203d are provided with the process chambers 202a to 202d, respectively. However, the technique of the present disclosure is not limited thereto. For example, the process vessel 203 serving as the second vessel may include a configuration in which a plurality of process chambers or a plurality of process spaces are provided.

Further, the embodiments or the modified examples mentioned above may be appropriately combined. The process procedures and the process conditions of each combination thereof may be substantially the same as those of the embodiments or the modified examples mentioned above.

The technique of the present disclosure may be preferably applied when the film is formed by using a batch type substrate processing apparatus capable of simultaneously processing a plurality of substrates or by using a single wafer type substrate processing apparatus capable of processing one substrate or several substrates at a time. In addition, the technique of the present disclosure may be preferably applied when the film is formed by using a substrate processing apparatus including a hot wall type process furnace or by using a substrate processing apparatus including a cold wall type process furnace. The process procedures and the process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

According to some embodiments of the present disclosure, it is possible to reduce the consumption amount of the inert gas.

What is claimed is:

1. A method of controlling an atmosphere, comprising:
(a) moving a substrate between a first vessel and a second vessel wherein a substrate is processed in the second vessel and the first vessel is capable of communicating with the second vessel;
(b) processing the substrate in the second vessel; and
(c) waiting without processing the substrate in the second vessel,
wherein an amount of an inert gas supplied into the first vessel in a state where an inner pressure of the first vessel is higher than that of the second vessel is adjusted such that the amount in (a) is greater than one or both of the amount in (b) and the amount in (c).

2. The method of claim 1, wherein, in (b) or in (c), a supply of the inert gas to the first vessel or an exhaust of an inner atmosphere of the first vessel is stopped, or both of the supply of the inert gas to the first vessel and the exhaust of the inner atmosphere of the first vessel are stopped.

3. The method of claim 1, wherein, in (b) or in (c), stopping a supply of the inert gas to the first vessel and stopping an exhaust of an inner atmosphere of the first vessel are performed with a predetermined time difference therebetween.

4. The method of claim 3, wherein the predetermined time difference is equal to a time duration in which the inner pressure of the first vessel is capable of being maintained higher than the inner pressure of the second vessel.

5. The method of claim 1, wherein an exhaust amount of an inner atmosphere of the first vessel exhausted from the first vessel is adjusted such that the exhaust amount in (a) is smaller than one or both of the exhaust amount in (b) and the exhaust amount in (c).

6. The method of claim 1, wherein the inner pressure of the first vessel is increased when a pressure difference between the inner pressure of the first vessel and the inner pressure of the second vessel exceeds a first threshold value.

7. The method of claim 6, wherein the inert gas is supplied into the first vessel when the pressure difference between the inner pressure of the first vessel and the inner pressure of the second vessel exceeds the first threshold value.

8. The method of claim 7, wherein an exhaust of an inner atmosphere of the first vessel is stopped or an exhaust amount of the inner atmosphere of the first vessel is reduced when the pressure difference between the inner pressure of the first vessel and the inner pressure of the second vessel exceeds the first threshold value.

9. The method of claim 6, wherein a supply of the inert gas is stopped when the pressure difference is lower than the first threshold value.

10. The method of claim 7, wherein the pressure difference between the inner pressure of the first vessel and the inner pressure of the second vessel is calculated.

11. The method of claim 7, wherein (b) comprises:
(b1) adjusting the inner pressure of the second vessel to a substrate processing pressure after the substrate is loaded into the second vessel,
(b2) processing the substrate by supplying a process gas to the second vessel; and
(b3) adjusting the inner pressure of the second vessel to a substrate transfer pressure after (b2), and
wherein, in the first vessel, the inner pressure of the first vessel is adjusted in synchronization with at least one among (b1), (b2) and (b3).

12. The method of claim 11, wherein (b2) comprises:
(b21) supplying a source gas to the substrate; and
(b22) supplying a reactive gas to the substrate,
wherein (b21) and (b22) are repeatedly performed a predetermined number of times, and
wherein, in the first vessel, the inner pressure of the first vessel is adjusted in synchronization with one or both of (b21) and (b22).

13. The method of claim 11, wherein the inner pressure of the first vessel is maintained to be higher than the inner pressure of the second vessel even when a pressure fluctuation occurs in at least one among (b1), (b2) and (b3) in the second vessel.

14. The method of claim 1, further comprising:
(d) depressurizing a load lock chamber capable of communicating with the first vessel; and
(e) moving the substrate between the load lock chamber and the first vessel,
wherein, in a state where an inner pressure of the load lock chamber is higher than the inner pressure of the first vessel, the amount of the inert gas supplied into the first vessel is set such that the amount in (d) is smaller than the amount in (e).

15. The method of claim 14, wherein the inner pressure of the first vessel is controlled to be higher than the inner pressure of the second vessel and to be lower than the inner pressure of the load lock chamber when the load lock chamber is in a reduced pressure state.

16. The method of claim 1, wherein the inner pressure of the first vessel is set to be equal to or higher than the inner pressure of the second vessel when moving the substrate from the first vessel to the second vessel, and thereafter the inner pressure of the first vessel is adjusted to be higher than the inner pressure of the second vessel by making the first vessel communicate with the second vessel.

17. A method of processing a substrate, comprising
the method of claim 1.

18. A method of manufacturing a semiconductor device, comprising
(a) moving a substrate between a first vessel and a second vessel wherein a substrate is processed in the second vessel and the first vessel is capable of communicating with the second vessel;
(b) processing the substrate in the second vessel; and
(c) waiting without processing the substrate in the second vessel,
wherein an amount of an inert gas supplied into the first vessel in a state where an inner pressure of the first vessel is higher than that of the second vessel is adjusted such that the amount in (a) is greater than one or both of the amount in (b) and the amount in (c).

19. A substrate processing apparatus configured to be capable of performing the method of claim 1.

20. A non-transitory computer-readable recording medium storing a program that causes a substrate processing apparatus, by a computer, to perform:
(a) moving a substrate between a first vessel and a second vessel wherein a substrate is processed in the second vessel and the first vessel is capable of communicating with the second vessel;
(b) processing the substrate in the second vessel; and
(c) waiting without processing the substrate in the second vessel,
wherein an amount of an inert gas supplied into the first vessel in a state where an inner pressure of the first vessel is higher than that of the second vessel is adjusted such that the amount in (a) is greater than one or both of the amount in (b) and the amount in (c).
